(19) United States
(12) Patent Application Publication
(10) Pub. No.: US 2016/0069557 A1
(43) Pub. Date: Mar. 10, 2016

(54) EXPLOSION-PROTECTED ARRANGEMENT OF ELECTRICAL AND/OR ELECTRONIC COMPONENTS

(71) Applicant: R. STAHL SCHALTGERÄTE GMBH, Waldenburg (DE)

(72) Inventor: Johannes Rückgauer, Künzelsau-Nagelsberg (DE)

(21) Appl. No.: 14/786,190

(22) PCT Filed: Apr. 15, 2014
(86) PCT No.: PCT/EP2014/057632

§ 371 Date: Oct. 22, 2015

(30) Foreign Application Priority Data
Apr. 26, 2013 (DE) 10 2013 104 240.6

(51) Int. Cl. F21V 25/12; H05K 7/14; F21V 29/76; H05K 7/20; F21V 31/00; F21V 17/16

(52) U.S. Cl. CPC F21V 25/12; F21V 31/005; F21V 17/16; F21V 29/763; H05K 7/205; H05K 7/14; F21Y 2105/001

(57) ABSTRACT

An explosion-protected arrangement (5) is provided that can be formed of a plurality of modules (49). Each module (49) has at least one covering part (20) and at least one carrier (13). The carrier (13) has a carrier face (12) on which electrical and/or electronic components (6) are arranged and in electrical contact. The covering body (20) has an underside (21) facing the carrier face (12) in which a plurality of receiving chambers (22) is formed. Each receiving chamber (22) is open via an opening (23) only on the underside (21) and is otherwise closed by the covering body (20). Webs (25) having web faces (26) surround the openings (23) and receiving chambers (22). When a connection is made between the covering body (20) and the carrier (13), each component (6) is surrounded by a web (25) with the web face (26) thereof forming a flame-proof gap (27) with an associated section of the carrier face (12).

### FIELD OF THE INVENTION

The present invention relates to an explosion-protected arrangement that comprises several electrical and/or electronic components and, in particular light-receiving and/or light-emitting components. Such electrical or electronic components include semiconductor elements such as, for example, semiconductor illuminants in the form of light-emitting diodes or luminescent diodes.

### BACKGROUND OF THE INVENTION

An electrical component as used herein is intended to include a separately handleable component unit with a shared housing and electrical connections existing on the housing. An integrated circuit with connecting pins on a shared housing is thus considered, for example, a single component, even though it has a plurality of transistors inside the housing. Such components are arranged on a carrier, for example a circuit board, or on a cooling body, and are electrically contacted via strip conductors, bonding wires or the like.

In potentially explosive areas such arrangements must be configured so as to be explosion-protected. To accomplish this, various options have been known. For example, publication GB 24 58 345 A has suggested that light-emitting diodes, as well as their carriers, be arranged in a sealed housing.

Publication DE 10 2010 018 784 A1 suggests, in general, that a pressure-resistant encapsulated partial housing be arranged on a circuit board so that the electrical components arranged on the circuit board are arranged within the pressure-resistant encapsulated partial housing. In so doing, the circuit board may be a component of the explosion-protected housing.

Another solution has been known from publications DE 10 2009 005 547 A1, as well as from US 2007/0194712 A1. They suggest the individual encapsulation of light-emitting diodes. A hood-shaped cover is arranged on the carrier and circumferentially connected to the carrier in a sealing manner. Consequently, the cover makes available an encapsulated receiving space for respectively one light-emitting diode. However, the encapsulation of all light-emitting diodes is very labor-intensive and cost intensive.

### OBJECTS AND SUMMARY OF THE INVENTION

It is an object of the present invention to provide an explosion-protected arrangement of electrical and/or electronic components that can be more easily assembled and handled.

The inventive explosion-protected apparatus arrangement comprises at least one carrier with at least one carrier face on which are arranged a plurality of electrical and/or electronic components such as, for example, light-receiving or light-emitting components, said components being arranged at a distance from one another. Furthermore, at least one covering body is provided. The covering body—if light-receiving or light-emitting components exist—may at least in part be made of material that is transmissive to the wavelength of the light emitted or received by the components. In so doing, the at least one covering body may be made completely in one piece of material that is transmissive to this lightwave length, i.e., without seams and joints, for example by a casting or injection molding process. Preferably, the covering body consists of plastic material.

Furthermore, the explosion-protected arrangement comprises a connecting device. This connecting device is disposed to create—preferably in a toolless manner—a nonpositive-locking and/or positive-locking connection between the at least one covering body and the at least one carrier. For example, by means of the connecting device, it is possible to establish a detent connection and/or a clamping connection between the at least one covering body and the at least one carrier. The connection established by the connecting device is preferably reversible in a non-destructive manner. Optionally, it is also possible to form a material-bonded connection by means of an adhesive joint between the at least one covering body and the at least one carrier.

The at least one covering body comprises at least a plurality of covering chambers for the components. Preferably, a maximum of 10, and further preferably, a maximum of 5 components, are arranged in each receiving chamber. In a preferred exemplary embodiment, a separate receiving chamber is provided for each component. In so doing, the number of receiving chambers may also correspond to the number of electrical and/or electronic components to be covered on the receiving surface. However, considering components that do not pose a risk of explosion—for example, intrinsically safe components—these can also be arranged outside a receiving chamber on the carrier, or individual components can be separately protected outside the receiving chambers of the covering body by another means, for example, by a casting compound.

Each receiving chamber is completely closed on five sides by the covering body and has an opening only on the side facing the carrier face. Consequently, the covering body can be simply set on the carrier face for enclosing the components. In so doing, preferably the connecting device is used for the nonpositive-locking and/or positive-locking connection with the associate carrier.

A circumferential web having a web face exists around each opening on the covering body. The web face or all the web faces of the covering body are preferably flat and extend in a common plane. With the connection established between the at least one covering body and the at least one carrier, the web faces form a flame-proof gap. Via the connecting device, the at least one covering body is secured to the at least one carrier, and the flame-proof gap is ensured.

In accordance with the invention the arrangement comprises only a few components: the electrical and/or electronic components that are arranged on the at least one carrier; the at least one covering body; and the connecting device that is arranged on the at least one carrier and/or on the at least one covering body. The arrangement can be assembled very easily in an explosion-protected manner. After mounting the components on the carrier and their electrical contacting, the covering body is simply set on the carrier face and held over the existing connecting device. Inasmuch as the individual receiving chambers display only a minimal volume, the pressure developing during an explosion inside a receiving chamber is very small. Therefore, the entire arrangement can be implemented in an accordingly light-weight design. Due to the use of several covering bodies and/or several carriers, the arrangement may further be designed in a modular manner, so that even great lengths and/or widths can be achieved in an explosion-protected arrangement, e.g., an illuminant.

The chamber volume of a receiving chamber is, in particular, at most 1.3 up to 1.5 times greater than the volume of the component(s) accommodated in the receiving chamber. Each receiving chamber has a maximum chamber volume of 1 cm³, in particular. With the connection established, the air volume remaining in the receiving chamber is thus only very minimal. The receiving chambers may be—but need not be—sealed relative to the environment. The formation of a flame-proof gap between the web faces and the carrier face around each receiving chamber is sufficient. In the preferred embodiment, the minimum width of the web or a web face may be 5 to 10 mm.

In a preferred embodiment, the weight of the web is prespecified as a function of the total volume of the receiving chamber and/or the remaining residual volume between the component and the associate receiving chamber. Consequently, a flame-proof gap can be formed between the individual receiving chambers as well as toward the environment, respectively, said gap being adapted to the size of the receiving chamber and being as small as possible in order to keep the overall size of the arrangement as small as possible.

A circuit board can be used, for example, as the carrier for electrical and/or electronic components. Alternatively, it is also possible to use the carrier as a cooling body. Likewise, a combination of a circuit board with a cooling body may be used as the carrier. Preferably, the carrier consists of metal, for example aluminum, or another material that is a good thermal conductor. It is also possible to arrange a thermally conductive layer, e.g., a graphite layer, between the components and the carrier face. Furthermore, for cooling the components, at least one coolant channel may be provided inside the carrier. The coolant channel can be connected to a coolant circuit so that thermal energy released by the electrical and/or electronic components can be removed by the coolant.

The connecting device disposed for establishing the connection between the at least one covering body and the at least one carrier may be embodied in many different types. The connection may be provided by a detent connection, a plug connection, a screw connection, a rivet connection and, optionally, by a material-bonded adhesive connection. In a preferred exemplary embodiment, the connecting device is disposed for providing a toolless, disconnectable, positive-locking and/or nonpositive locking connection. To accomplish this, the connecting device comprises at least one detent means or plug means on each covering body and/or on each carrier. Each detent means or plug means is associated with a counter-detent means or counter-plug means on the correspondingly other part, i.e., on the carrier or on the covering body. With the connection established, the detent means and the counter-detent means or the plug means and the counter-plug means interact between the respective covering body and the associate carrier.

In order to improve the type of protection (IP rating) in compliance with IEC 60529, a sealing arrangement may be arranged between the at least one covering body and the at least one carrier. For example, the sealing arrangement may extend in an annular closed manner around all the receiving chambers of a covering body. The sealing arrangement may be provided in a sealing groove of the covering body and/or on the carrier.

An advantageous embodiment of the invention comprises a coupling device. In this case, at least one of the covering bodies and/or one of the carriers comprises a coupling means and/or a counter-coupling means. The coupling means and an associate counter-coupling means interact to establish a preferably disconnectable connection. In this manner, two covering bodies and/or carriers can be reversibly connected to each other via the coupling device, so that a modular design can be implemented. Consequently, two covering bodies and/or carriers can be connected via the coupling means in a nonpositive-locking and/or positive-locking manner, preferably without tools and, in particular, in a disconnectable manner. The coupling means and the counter-coupling means may also comprise electrical contact means and electrical counter-contact means, respectively, so that—at the same time—an electrical connection is established between two covering bodies and/or carriers that are connected to each other.

Respectively at least one carrier having the electrical and/or electronic components and at least one covering body may form a module. Preferably, each module has at least one coupling means and/or at least one counter-coupling means. Consequently, several modules can be coupled to each other in one spatial direction or also in two spatial directions. Thus, the arrangement can be flexibly designed in a modular manner. For example, if the modules comprise semiconductor illuminants such as light-emitting diodes, a highly simple modular explosion-protected illuminant having basically any desired length and/or surface can be designed.

The explosion-protected module can be assembled in a very simple manner via the connecting device. Individual modules can be combined rapidly and simply by means of the connecting device. Also, modules having different functions can be connected to form a unit. For example, a module with light-receiving components may act as a motion detector and switch illuminants on and/or off.

If an associate carrier or a module comprises light-receiving and/or light-emitting components, the at least one covering body for each receiving chamber, and thus the component for each light-receiving and/or light-emitting component, may comprise an optical element. The optical element is disposed for guiding, focusing, scattering, refracting or the like, the light that is to be received and has been emitted by the associate component or is impinging in the receiving chamber. Such an optical element is preferably transmissive to the wavelength of light emitted or to be received by the component.

For example, the optical element may be a lens. The optical element may also be an integral part of the covering body or be arranged on the upper side of the covering body, facing away from the carrier. Consequently, an optical element may form a converging lens or a diverging lens. Alternatively or additionally, it is also possible to integrate a plurality of transparent and/or opaque particles for scattering, refracting, reflecting or deflecting light. By means of the configuration and dimensioning of the covering plate and/or the optionally existing optical element, it is also possible to affect the radiation density of the light emitted by the light-emitting diodes or other light-emitting components, in particular, in order to comply with the requirements of explosion protection in view of beam density.

Other objects and advantages of the invention will become apparent upon reading the following detailed description and upon reference to the drawings.

### BRIEF DESCRIPTION OF THE DRAWINGS

FIG. 1 is a schematic plan view of an exemplary embodiment of an explosion-protected arrangement in accordance with the invention comprising electrical and/or electronic components;

FIG. 2 is a vertical section of the illustrated explosion-protected arrangement taken in the plane of line II-II in FIG. 1;

FIG. 3 is an exploded sectional view of the explosion-protected arrangement shown in FIG. 2;

FIG. 4 is an enlarged fragmentary section of the exemplary embodiment shown in FIGS. 1-3;

FIG. 5 is a schematic side elevational view of a plurality of modules comprising an explosion-protected arrangement in accordance with the invention;

FIG. 6 is a schematic side elevational view of another embodiment of a plurality of modules comprising an explosion-protected arrangement in accordance with the invention; and

FIG. 7 is a top plan view depicting a coupling device of the plurality of modules shown in the exemplary embodiments.

While the invention is susceptible of various modifications and alternative constructions, certain illustrative embodiments thereof have been shown in the drawings and will be described below in detail. It should be understood, however, that there is no intention to limit the invention to the specific forms disclosed, but on the contrary, the intention is to cover all modifications, alternative constructions, and equivalents falling within the spirit and scope of the invention.

### DETAILED DESCRIPTION OF THE PREFERRED EMBODIMENTS

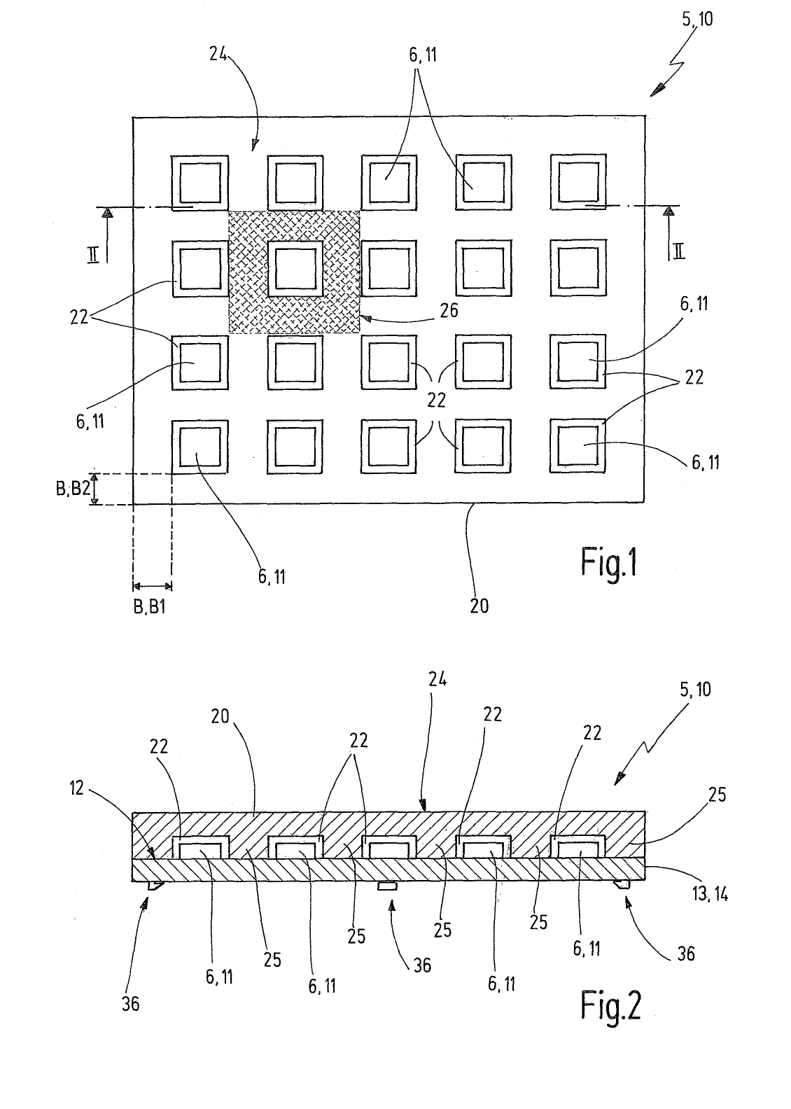

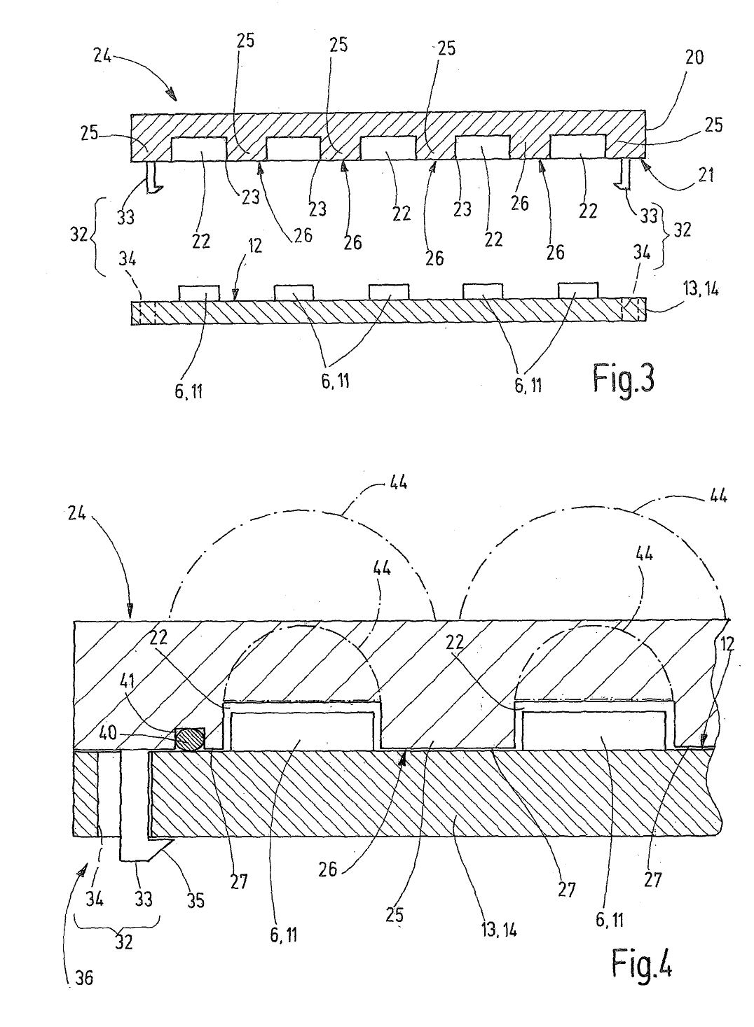

Referring now more particularly to FIGS. 1-4 of the drawings, there is shown an illustrative embodiment of an explosion-protected apparatus arrangement 5 in accordance with the invention comprising several electrical and/or electronic components. The components 6 may be of the most diverse types. In particular, they may be semiconductor components and/or light-emitting components and/or light-receiving components. In the exemplary embodiments described hereinafter, the arrangement 5 is configured as an illuminant arrangement 10. The electrical and/or electronic components 6 are formed by semiconductor illuminants and, for example, by light-emitting diodes 11. The arrangement 5 according to the invention may additionally or alternatively also comprise any other desired components 6.

The illuminant arrangement 10 comprises a plurality of semiconductor illuminants that, in the exemplary embodiment, are the light-emitting diodes 11. However, instead of the light-emitting diodes 11, it would also be possible to use other semiconductor illuminants such as luminescent diodes.

The components 6 embodied as light-emitting diodes 11 according to the example are arranged at a distance from each other on a carrier face 12 of a carrier 13. In accordance with the example the carrier face 12 is planar and extends in one plane. In addition to the light-emitting diodes 11, it is also possible to arrange strip conductors, electrical connecting lines or the like on the carrier face 12. The electrical contacting of the light-emitting diodes 11 is not specifically illustrated by the Figures. Such contacting may take place via the strip conductors and/or bonding wires or the like. If the carrier 13 consists of an electrically conductive material, an electrically isolating layer may at least be provided on part of the carrier face 12 in order to avoid electrical short-circuiting.

As explained, it is possible, alternatively or additionally to the light-emitting diodes 11, to also mechanically mount additional electrical and/or electronic components 6 on the carrier and to provide electrical contacts therefor.

Referring to the exemplary embodiments of the arrangement 5 or the illuminant arrangement 10 in accordance with FIGS. 1 to 5, the carrier 13 is a circuit board 14. As an alternative thereto, the carrier 13 may also be a cooling body 15 on which the carrier face 12 is directly provided. It is also possible for the carrier 13 to be formed of a combination of the circuit board 14 and the cooling body 15, as is shown, for example, by FIG. 6.

Depending on the embodiment of the carrier 13, it may be made of different materials. Preferably, the carrier 13 consists of a material that is a good thermal conductor, for example a metallic material, in particular aluminum, or it comprises an aluminum layer or an aluminum core. Additionally or alternatively, it is also possible for thermally conductive layers to be provided on the carrier 13, for example layers with graphite.

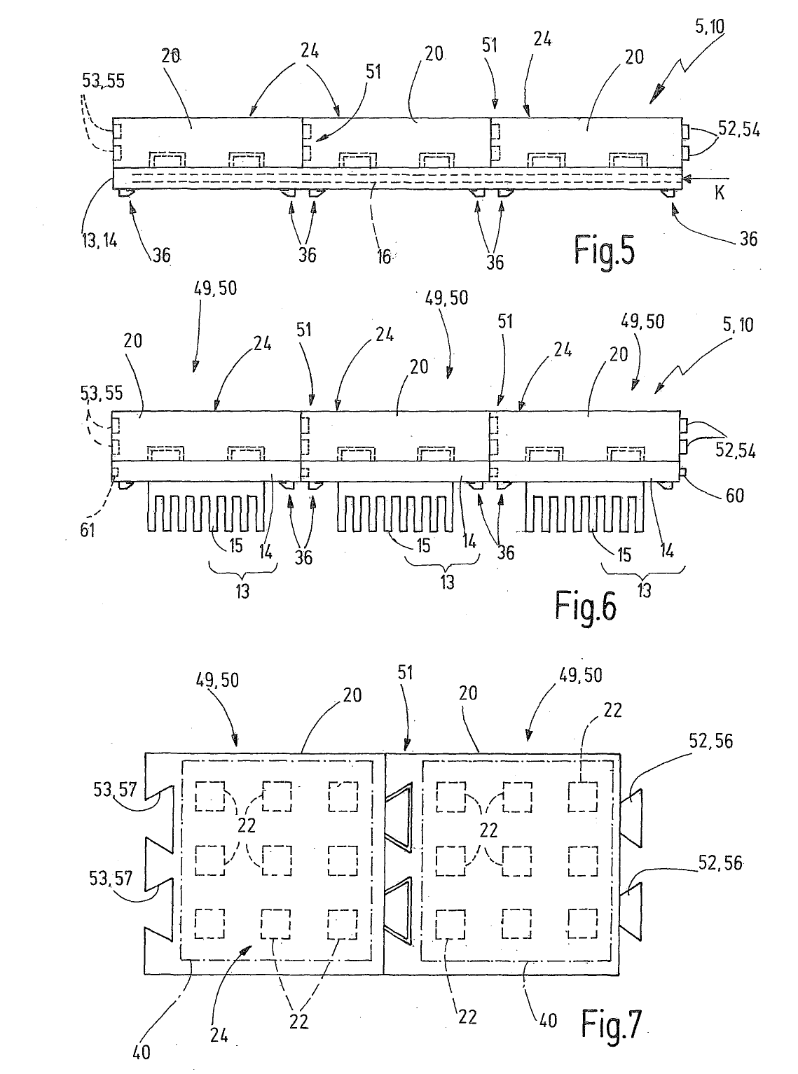

Referring to the exemplary embodiment shown by FIG. 5, a coolant channel 16 is provided on the carrier 13—in accordance with the example in the circuit board 14, said coolant channel being depicted only schematically. The coolant channel 16 may meander or move in arches or loops or the like through the circuit board 14. It can be connected at least at one point to the coolant circuit, so that coolant K may circulate through the coolant channel 16, as is schematically illustrated by the arrow in FIG. 5.

Furthermore, in accordance with the example, the arrangement 5 formed by the illuminant arrangement 10 comprises a covering body 20. Several concave recesses are formed in the covering body 20 on an underside 21 associated with the carrier face 12, each of said recesses representing a receiving chamber 22. Each receiving chamber 22 is open on the underside 21 of the covering body 20 via a single opening 23 and is otherwise circumferentially closed by the covering body 20. The upper side 24 of the covering body 20 opposite the underside 21 represents the light-emitting side or the light-emitting face of the illuminant arrangement 10 in accordance with the example. The covering body 20 may be made in part or fully of material that is transmissive to the wavelength of the light emitted by the semiconductor illuminant means. This transmissivity to light exists at least in the region of a receiving chamber 22, whenever a light-emitting component (here: light-emitting diode 11) and/or a light-receiving component are provided. The covering body 20 may also be opaque to light in other applications.

A web 25 is formed circumferentially around the opening 23 of each receiving chamber 22 on the covering body 20. Each web 25 has a web face 26. The web face 26 is associated with the carrier face 12 of the carrier 13. The web faces 26 of the webs 25 of a covering body 20 are preferably flat and extend in a common plane. FIG. 1 shows only schematically an example of the web face 26 for one of the webs 25 in a dotted line, said web enclosing the associate receiving chamber 22 in an annular manner. The web section between two directly adjacent receiving chambers 22 is thus a component of the web 25 around the one receiving chamber 22, as well as of the web 25 around the directly adjacent receiving chamber 22.

Furthermore, FIG. 1 depicts the width B of a web 25 or the web face 26 in one location, for example. The width B may have different dimensions B1, B2 in different sections of a web 25. Important is that the width B not be smaller at any point than a prespecified minimum value. The width B or the minimum value for the width B can be determined as a function of the total volume of a receiving chamber 22 and/or of the remaining partial volume between a component 6, for example a light-emitting diode, and the surface of the covering body 20 delimiting the receiving chamber 22. This minimum width of the web 25 or the web face 26 is disposed to form a flame-proof gap 27 between the covering body 20 and the associate carrier 13 (FIG. 4) when the covering body 20 and the carrier 13 are connected.

The flame-proof gap 27 is thus formed by the web face 26 of a circumferential web 25 around a receiving chamber 22 and the associate face section on the carrier face 12 of the carrier 13, which is schematically illustrated by FIG. 4. Consequently, by placing the covering body 20 on the carrier 13 in a manner that, in accordance with the example, respectively one component 6 or one light-emitting diode 11 is arranged in one receiving chamber 22, it is possible to achieve—in a simple manner—an explosion-protected arrangement 5 or illuminant arrangement 10. In modification of the exemplary embodiment, it is also possible to arrange, in a receiving chamber 22, several—in particular five or ten—components. For example, one light-emitting diode 11 may be arranged with its directly associate wiring through a capacitor and/or a diode in a receiving chamber 22.

The connection between the covering body 20 and the carrier 13 is preferably a detachable, positive-locking and/or nonpositive locking connection. In addition, it is also possible to provide a material-bonded connection between the covering body 20 and the carrier 13. Each receiving chamber 22 comprising a component 6 or a light-emitting diode 11 is designed in an explosion-proof manner by way of a flame-proof gap 27 relative to the environment and/or with respect to the adjacent receiving chamber(s) 22. In so doing, a material-bonded sealing of the individual receiving chambers 22 relative to the carrier 13 may be dispensed with. Small volumes separated from each other by webs 25 and flame-proof gaps 27 are formed in the receiving chambers 22, which greatly simplifies the achievement of explosion protection.

A connecting device 32 is provided for connecting the covering body 20 and the carrier 13. In the preferred exemplary embodiment, the connecting device 32 is disposed for the toolless detachable connection between the covering body 20 and the carrier 13. To accomplish this, the connecting device 32 has at least one detent means 33 and one counter-detent means 34 interacting with said detent means in order to establish the connection. As an alternative to the detent means 33 and the counter-detent means 34, there may also be a plug means and a counter-plug means. Likewise, a combination of different means for establishing a positive-locking and/or nonpositive-locking connection is possible.

As described in detail, the shown exemplary embodiment comprises a detent means 33 and a counter-detent means 34. The one or more detent means 33 may be provided on the covering body 20 and/or on the carrier 13. The counter-detent means 34 associated with each detent means 33 is then arranged on the respectively other part, i.e., the carrier 13 or the covering body 20. The number of detent means 33 and counter-detent means 34 may vary and depends on the form and dimensions of the covering body 20 or the carrier 13.

In the depicted exemplary embodiments, the detent means 33 are located on the covering body 20. For example, they are embodied as engagement hooks with a snap tab 35 and may be molded to the covering body 20. The detent means 33 can thus be connected to the covering body already during the manufacture of the covering body 20 by casting or injection-molding, or they may be manufactured as a part of the covering body 20.

The counter-detent means 34 are formed by openings in the carrier 13 and, in accordance with the example, the circuit board 14. With the connection between the covering body 20 and the carrier 13 established, the engagement hook being the detent means 33 engages through the openings representing the counter-detent means 34 and extends around the carrier face 12 of the opposite side (FIG. 4).

FIG. 4 shows only as an example a detent connection at one location. The other detent connections may be embodied accordingly. The number of and the distance between the connecting locations 36 by means of a detent means 33 or a plug means and a correspondingly associate counter-detent means 34 and counter-plug means vary depending on the size and shape of the covering body 20 and the carrier 13. The number of connecting locations 36 is selected in such a manner that the flame-proof gap 27 around each receiving chamber 22 remains maintained even in situations of mechanical loads or thermal deformation.

The connecting device 32 thus ensures that the covering body 20 is held on, and secured by, the carrier 13, so that the flame-proof gap 27 is formed and maintained between the web faces 26 and the respectively opposite section of the carrier face 12. Consequently, it is possible in a very simple manner to achieve an explosion-protected arrangement or illuminant arrangement 10. The assembly and handling are greatly simplified. In the case of a detachable connection, it is possible by means of the connecting device 32 to maintain and repair the arrangement 5 of the illuminant arrangement 10 in a simple manner.

In order to achieve or improve the type of protection in compliance with IEC 60529, a sealing arrangement 40 may be provided between the covering body 20 and the carrier 13. Referring to the exemplary embodiment depicted here, the sealing arrangement 40 comprises an annularly closed seal that extends around each and every receiving chamber 22 or opening 23 existing in the covering body 20 and thus minimizes or prevents the ingress of particles, dust or water. The sealing arrangement 40 is shown greatly simplified by FIGS. 4 and 7. The sealing arrangement 40 may be arranged in a sealing groove 41 on the covering body 20 and/or on the carrier 13.

FIG. 4 also shows a potential modification of the described exemplary embodiments—indicated in chain lines. This modification can be used for arrangements 5 that comprise light-emitting components 6 and/or light-receiving components 6, namely for the embodiments of the illuminant arrangement 10 described here, for example.

One or more optical elements 44 may be arranged on or formed as an integral part of the covering body 20 and/or be arranged on the upper side 24 of the covering body 20. Preferably, each receiving chamber 22 and thus each light-emitting diode 11 is associated with an optical element 44. Such optical elements 44 may be configured so as to be transmissive to the light wavelength of the light-emitting diode 11 and be disposed for the formation of converging lenses or dispersing lenses in or on the covering body 20. As a result of this, it is possible to change the light distribution. In addition to or instead of lenses, the optical elements 44 may also comprise a plurality of light-scattering and/or light-reflecting and/or light-refracting particles.

The beam density of the light emitted by the light-emitting diodes 11 can be adjusted via the shape and dimensioning of the covering plate 24 or the optionally provided optical elements 44. The beam density can thus be varied via the configuration of the covering body 20 and/or the optionally present optical elements 44 in order to comply with the regulations of explosion protection.

The arrangement 5 or the illuminant arrangement 10 may be set up in a modular design of several and, in principle, any desired number of modules 49 that, in the present case, are embodied as luminous modules 50. A connection of several modules 49 or luminous modules 50 is illustrated by FIG. 6, for example. It shows three modules 49 that are connected together. A module 49 may also include several covering bodies 20 that are associated with a shared carrier 13 (FIG. 5). Alternatively, it would also be possible that a module 49 have a covering body 20 that is associated with several carriers 13. Preferably, each module 49 or luminous module 50 has a single covering body 20 or a single carrier 13 with a circuit board 14 and/or a cooling body 15. This design is shown by FIG. 6.

For the connection of two modules 49 or luminous modules 50 together, a coupling device 51 is provided in accordance with the example. The coupling device 51 is disposed for providing a positive-locking and/or nonpositive-locking coupling between two directly adjacent modules 49 or luminous modules 50. In accordance with the example, the coupling device 51 is only arranged on the covering body 20; however, alternatively or additionally, it could also be arranged on the carriers 13 of the modules 49 or luminous modules 50 that are to be connected.

In the preferred exemplary embodiment, the coupling device 15 is disposed to provide a toolless, releasable connection between two modules 49. To accomplish this, the coupling device preferable has, on each covering body 20 and/or carrier 13, a coupling means 52 and a counter-coupling means 53 interacting with the coupling means 52. Each coupling means 52 is associated with a counter-coupling means 53 in order to establish a positive-locking and/or nonpositive-locking connection. Referring to the depicted exemplary embodiment according to FIGS. 5 and 6, the coupling means 52 are formed by a plug projection 54 that is associated with a plug recess 55, the latter representing the counter-coupling means 53. Consequently, a nonpositive-locking plug connection can be established between the covering bodies 20 and the modules 49, respectively.

As is schematically shown by FIGS. 5 and 6, the coupling means 52 are provided on one lateral surface and the counter-coupling means 53 are provided on the respectively opposite lateral surface of a covering body 20, so that the covering bodies 20 can be connected to each other in a manner similar to plug blocks. Additionally or alternatively, the coupling means 52 or the counter-coupling means 53 could also be present on the two other lateral surfaces, so that not only a series of covering bodies 20 is possible but also a two-dimensional planar coupling in two spatial directions is possible.

FIG. 7 shows an alternative embodiment option of the coupling device 51. In so doing, a positive-locking connection is formed between the coupling means 52 and the counter-coupling means 53. For this purpose, the coupling means 52 are, respectively, formed by a widening projection 56. Adapted to the contour of the projection 56, the respectively associate counter-coupling means 53 is formed by an outward-tapering recess 57. The respective projection 56 can engage in a positive-locking manner in the respectively associate recess 57 and thus form a positive-locking connection as is schematically illustrated by FIG. 7.

In the example illustrated in FIG. 7, the projections 56 and the recesses 57 have the shape of a dove-tail. Different therefrom, it is also possible to use different configurations of undercuts, for example in the form of projections and recesses as are known from puzzle pieces.

In addition, the coupling device 51 may also establish an electrical connection between two coupled modules 49. To accomplish this, electrical contact means 60 and/or electrical counter-contact means 61 may be provided, in particular, on the carrier 13 of a module 49, these creating—in case of a mechanical coupling by the coupling means 52 and the counter-coupling means 53—an electrical connection between the two coupled modules 49, as is schematically illustrated by FIG. 6.

As an alternative to the illustration of FIG. 6, the contact means 60 may also be provided on the coupling means 52 and the counter-contact means 61 on the counter-coupling means. For example, respectively one electrically conductive contact surface may be present as the contact means 60 on the projections 56 and 54, respectively, and as the counter-contact means 61 on the recess 55 and 57, respectively.

From the foregoing, it can be seen that the invention relates to an explosion-protected arrangement 5, for example an illuminant arrangement 10. The arrangement 5 may be made up of several modules 49. Each module 49 comprises at least one covering body 20 and at least one carrier 13. The carrier 13 has a carrier face 12, on which electrical and/or electronic components 6, for example semiconductor illuminant means such as light-emitting diodes 11, are arranged and electrically contacted. The covering body 20 has a carrier face 12 associated with the underside 21 in which receiving chambers 22 are provided. Each receiving chamber 22 is only open on the underside 21 via an opening 23 and is otherwise closed by the covering body 20. Webs 25 with web faces 26 delimit the openings 23 or receiving chambers 22. With the connection between the covering body 20 and the carrier 13 established, preferably each component or a component assembly comprising several components 6 are annularly enclosed by a web 25, in which case the web face 26 forms a flame-proof gap 27 with the associate section of the carrier face 12.

### LIST OF REFERENCE SIGNS

5 Explosion-protected arrangement
6 Electronic component
10 Illuminant arrangement
11 Light-emitting diode
12 Carrier face
13 Carrier
14 Circuit board
15 Cooling body
16 Coolant channel
20 Covering body
21 Underside of the covering body
22 Receiving chamber
23 Opening
24 Upper side of the covering body
25 Web
26 Web face
27 Flame-proof gap
32 Connecting device
33 Detent means
34 Counter-detent means
35 Snap tab
36 Connecting location
40 Sealing arrangement
41 Sealing groove
44 Optical element
49 Module
50 Luminous module
51 Coupling device
52 Coupling means
53 Counter-coupling means
54 Plug projection
55 Plug recess
56 Projection
57 Recess
60 Contact means
61 Counter-contact means
B Width of the web
B1, B2 Dimensions of width B
K Coolant

1-18. (canceled)

19. An explosion-protected apparatus (5) comprising
at least one carrier (13) having one carrier face (12) on which are arranged a plurality of electrical and/or electronic components at a distance from one another,
at least one covering body (20),
a connecting device (32) arranged on the at least one covering body (20) and/or on the at least one carrier (13) for establishing a locking connection between the at least one covering body (20) and the at least one carrier (13),
said at least one covering body (20) having a plurality of receiving chambers (22) for receiving at least a part of said components (6), said receiving chambers (22) each having an opening (23) only on a side facing the carrier face (12),
a web (25) having a web face (26) extending circumferentially around the opening (23) of each receiving chamber (22), and
said connecting device securing together said at least one covering body (20) and at least one carrier (13) with said web face (26) and carrier face (12) forming a flame-proof gap (27).

20. The explosion-protected apparatus of claim 19 in which said carrier device (32) establishes a positive locking connection between the at least one covering body (20) and the at least one carrier (13).

21. The explosion-protected apparatus of claim 19 in which said carrier device (32) establishes a nonpositive locking connection between the at least one covering body (20) and the at least one carrier (13).

22. The explosion-protected apparatus of claim 19 in which each of said electrical and/or electronic component (6) is arranged in said receiving chamber (22).

23. The explosion-protected apparatus of claim 19 in which the web (25) has a width (B) determined as a function of the total volume of the receiving chamber (22).

24. The explosion-protected apparatus of claim 19 in which the web (25) has a width (B) determined as a function of the remaining residual volume between the component (6) and the associated receiving chamber (22) in which it is received.

25. The explosion-protected apparatus of claim 19 in which said at least one covering body (20) is made of a cohesive material without seams and joints.

26. The explosion-protected apparatus of claim 19 in which said at least one carrier (13) is a circuit board (14).

27. The explosion-protected apparatus of claim 19 in which said at least one carrier (13) comprises a cooling body (15).

28. The explosion-protected apparatus of claim 27 in which said at least one carrier (13) includes at least one coolant channel (16).

29. The explosion-protected apparatus of claim 19 in which said at least one carrier (13) consists of metal.

30. The explosion-protected apparatus of claim 19 in which said connecting device (32) comprises at least one detent (33) or plug on each covering body (30) and/or on each carrier (13) that is associated, respectively, with a counter-detent (34) or a counter-plug on each carrier (13) and/or covering body (20), respectively.

31. The explosion-protected apparatus of claim 19 including a sealing arrangement (40) between the at least one covering body (20) and the at least one carrier (13).

32. The explosion-protected apparatus of claim 19 in which said at least one carrier (13) with the electrical and/or electronic components (6) arranged thereon and said at least one covering body (20) form a module (49).

33. The explosion-protected apparatus of claim 32 in which two of said modules (49) can be connected via a coupling device (51), and each module having a coupling element (52) and/or a counter-coupling element (53) of the coupling device (51).

34. The explosion-protected apparatus of claim 33 in which two of said modules (49) can be connected to one another via the coupling device (51) in a positive-locking and/or nonpositive-locking manner.

35. The explosion-protected apparatus of claim 33 in which said coupling element (52) and/or the counter-coupling element (53) are arranged on the carrier (13) and/or the covering body (20) of a module (49).

36. The explosion-protected apparatus of claim 19 in which at least some of said components (6) are light-emitting components (11) and/or light-receiving components.

37. The explosion-protected apparatus of claim 36 in which said covering body (20) is at least in part transmissive to the wavelength of the light emitted by the light-emitting components (11) and/or impinges in the light-receiving components in the receiving chamber (22).

38. The explosion-protected apparatus of claim 36 including an optical element (44) on said covering body (20) opposite the carrier (13).
